(19) United States
(12) Patent Application Publication
(10) Pub. No.: US 2025/0218852 A1
(43) Pub. Date: Jul. 3, 2025

(54) WAFER PROCESSING APPARATUS

(71) Applicant: Powerchip Semiconductor Manufacturing Corporation, Hsinchu (TW)

(72) Inventors: Chia Chung Hsieh, Hsinchu (TW); Hsiao Wei Huang, Hsinchu (TW); Shun Chieh Chang, Hsinchu (TW)

(73) Assignee: Powerchip Semiconductor Manufacturing Corporation, Hsinchu (TW)

(21) Appl. No.: 18/426,281

(22) Filed: Jan. 29, 2024

(30) Foreign Application Priority Data
Jan. 2, 2024 (TW) 113100093

(51) Int. Cl. H01L 21/683; C23C 16/455; C23C 16/458; C23C 16/46; C23C 16/52; H01F 7/02

(52) U.S. Cl. CPC H01L 21/6838; C23C 16/45589; C23C 16/4586; C23C 16/46; C23C 16/52; H01F 7/0236

(57) ABSTRACT

The invention provides a wafer processing apparatus configured to interact with a wafer using a reactive gas. The wafer processing apparatus includes: a base having a carrying plane configured to carry the wafer, and the wafer has a first height and a second height; an air guide device disposed circumferentially above the base, there is a space between the base and the air guide device so that the reactive gas flows in the space; a first magnet disposed at a periphery of the base; a second magnet disposed at a periphery of the air guide device and opposite to the first magnet; a magnetic levitation control system electrically connected to the first magnet and controlling a magnetic force between the first magnet and the second magnet according to a difference of the second height and the first height to change a distance between the base and the air guide device.

### CROSS-REFERENCE TO RELATED APPLICATION

This application claims the priority benefit of Taiwan application serial no. 113100093, filed on Jan. 2, 2024. The entirety of the above-mentioned patent application is hereby incorporated by reference herein and made a part of this specification.

### BACKGROUND OF THE INVENTION

### Field of the Invention

The invention relates to a wafer processing apparatus.

### Description of Related Art

Chemical vapor deposition (CVD) is an important process step in the semiconductor manufacturing process. A reactive gas is transferred into a vacuum chamber and reacted on a substrate to form a thin film. When the wafer surface is uneven, i.e., warping at the edge, the thickness of the thin film at the edge may be abnormal. Therefore, how to overcome wafer warpage and form a thin film with uniform thickness is an important issue in the semiconductor manufacturing process.

### SUMMARY OF THE INVENTION

The invention provides a wafer processing apparatus to solve the issue of uneven thin film thickness caused by edge warping during the coating process.

The invention provides a wafer processing apparatus configured to interact with a wafer using a reactive gas and including: a base having a carrying plane, the carrying plane is configured to carry the wafer, and the wafer has a first height and a second height; an air guide device disposed circumferentially above the base, there is a space between the base and the air guide device so that the reactive gas flows in the space; a first magnet disposed at a periphery of the base; a second magnet disposed at a periphery of the air guide device and opposite to the first magnet; and a magnetic levitation control system electrically connected to the first magnet and controlling a magnetic force between the first magnet and the second magnet according to a difference of the second height and the first height to change a distance between the base and the air guide device.

According to some embodiments of the invention, the base includes a heater configured to heat the wafer, and the carrying plane is located on the heater.

According to some embodiments of the invention, the base further includes a vacuum port, and the vacuum port is located on the carrying plane and configured to generate a low-pressure area between the wafer and the vacuum port.

According to some embodiments of the invention, the first height is an average height on the wafer at a first distance from a center of the wafer, and the second height is an average height on the wafer at a second distance from the center of the wafer, wherein a range of the first distance is 0.4 to 0.6 of a wafer radius, and a range of the second distance is 0.8 to 1.0 of the wafer radius.

According to some embodiments of the invention, the periphery of the base includes a second carrying plane, the first magnet is disposed at the second carrying plane, and an upper surface of the first magnet is at a same height as the second carrying plane.

According to some embodiments of the invention, the air guide device includes an air guide ring, the air guide ring has a third carrying plane, the third carrying plane is opposite to the base, and the second magnet is disposed on the third carrying plane.

According to some embodiments of the invention, the air guide device further includes a non-contact ring, the non-contact ring is disposed above the air guide ring, and an inner diameter of the non-contact ring is less than an inner diameter of the air guide ring.

According to some embodiments of the invention, the air guide device further includes a projection of the inner diameter of the non-contact ring along a normal direction of the carrying plane overlapping the wafer.

According to some embodiments of the invention, the first magnet is an electromagnet and the second magnet is a permanent magnet.

According to some embodiments of the invention, a number of the first magnet is greater than one, and a number of the second magnet is greater than one.

According to some embodiments of the invention, a number of the first magnet is equal to a number of the second magnet.

According to some embodiments of the invention, the magnetic levitation control system includes: a first sensor and a second sensor, wherein the first sensor is configured to measure the first height of the wafer, and the second sensor is configured to measure the second height of the wafer.

According to some embodiments of the invention, the magnetic levitation control system further includes: a third sensor, wherein the third sensor is configured to measure a magnetic levitation distance between the base and the air guide device.

According to some embodiments of the invention, the magnetic levitation control system further includes: a controller, a magnetic levitation driver, a magnetic levitation system, and a signal conditioning box, wherein the controller is electrically connected to the first sensor, the second sensor, the signal conditioning box, and the magnetic levitation driver, the controller receives a first signal corresponding to the first height from the first sensor, a second signal corresponding to the second height from the second sensor, a third signal corresponding to the magnetic levitation distance from the signal conditioning box, and generates a control signal according to the first signal, the second signal, and the third signal and inputs the control signal to the magnetic levitation driver, the magnetic levitation driver is electrically connected to the magnetic levitation system, and the magnetic levitation driver outputs a control voltage to the magnetic levitation system according to the received control signal, the magnetic levitation system includes the first magnet and the third sensor, the magnetic levitation system is electrically connected to the signal conditioning box, the first magnet generates a magnetic force according to the control voltage, and the third sensor measures the magnetic levitation distance and transmits the magnetic levitation distance to the signal conditioning box, and the signal conditioning box generates the third signal corresponding to the magnetic levitation distance according to the magnetic levitation distance.

According to some embodiments of the invention, the controller is a digital-to-analog converter.

According to some embodiments of the invention, the signal conditioning box is an analog-to-digital converter.

According to some embodiments of the invention, the wafer processing apparatus further includes a plurality of wafer lifting pin channels, so that the wafer is moved via the plurality of wafer lifting pin channels.

Based on the above, according to the height difference of the central portion and the edge of the wafer, the distance between the base and the air guide device may be controlled via the magnetic levitation control system of the wafer processing apparatus to ensure that the gap of the air guide device and the wafer is a fixed value, so that the reactive gas in the chemical vapor deposition process may uniformly surround the wafer surface, so that the thickness of the thin film formed on the wafer surface is uniform.

### BRIEF DESCRIPTION OF THE DRAWINGS

FIG. 1 is a schematic diagram of a coating system.

FIG. 2 is a schematic diagram of measuring the height of a wafer according to an embodiment of the invention.

FIG. 3 is a schematic diagram of a wafer processing apparatus according to an embodiment of the invention.

FIG. 4 is a schematic diagram of a magnetic levitation control system according to an embodiment of the invention.

FIG. 5 is a top view of a base according to an embodiment of the invention.

FIG. 6 is a top view of an air guide ring according to an embodiment of the invention.

FIG. 7 is a schematic diagram of a wafer processing apparatus according to an embodiment of the invention.

FIG. 8 is a schematic diagram of a wafer processing apparatus according to an embodiment of the invention.

FIG. 9 is a flowchart of a coating method according to an embodiment of the invention.

### DESCRIPTION OF THE EMBODIMENTS

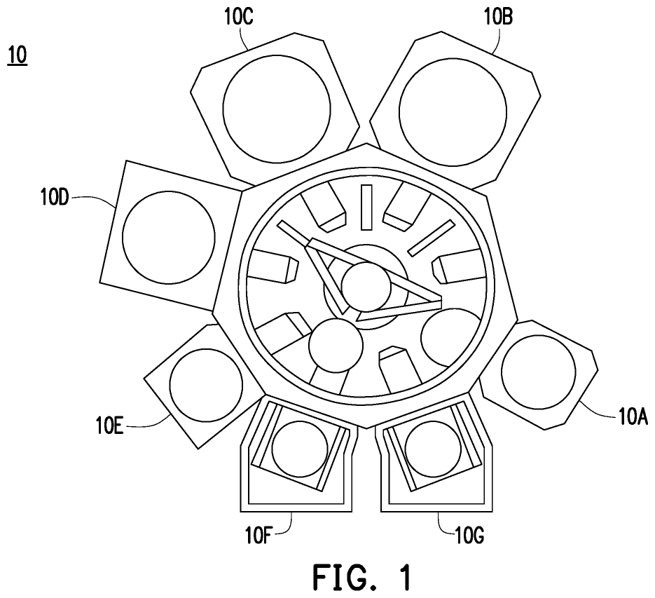

FIG. 1 is a schematic diagram of a coating system. Please refer to FIG. 1. A coating system 10 shown in FIG. 1 has a plurality of working chambers 10A to 10G. The wafers to be processed are sequentially fed into one or a plurality of the working chambers according to the required steps. In some embodiments, the working chamber 10A may measure the surface flatness of the wafer and check whether there is warpage at the wafer edge. In some embodiments, the working chamber 10B, the working chamber 10C, and the working chamber 10D may coat the wafer. In some embodiments, the working chamber 10E may cool the wafer after coating. In some embodiments, the working chamber 10F and the working chamber 10G may be configured to perform different processing steps on the wafer according to needs. In some embodiments, the number and the type of the working chambers of the coating system 10 may be determined according to needs, and the disclosure is not limited thereto. In some embodiments, wafers in the coating system may enter or leave the coating system by robotic arm or conveyor belt, or may be transferred between the working chambers, but the disclosure is not limited thereto.

The following explains how to measure warpage degree of the wafer edge.

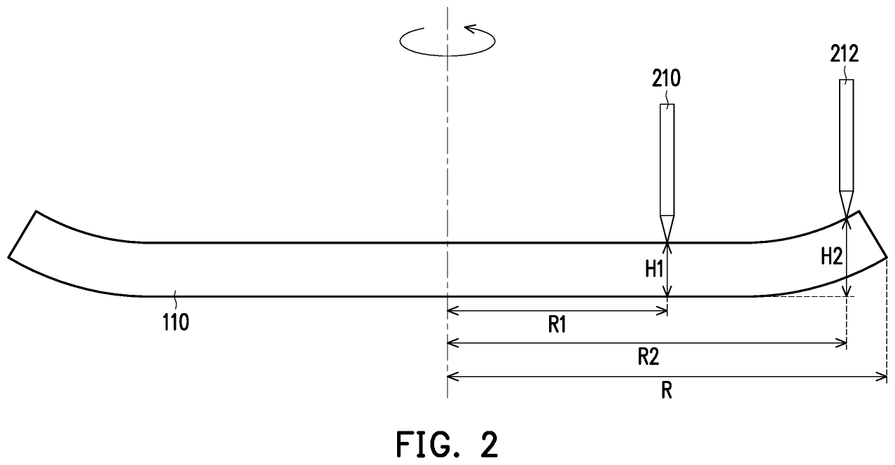

FIG. 2 is a schematic diagram of measuring the height of a wafer according to an embodiment of the invention. As shown in FIG. 2, a wafer 110 is located in the working chamber 10A, and the warpage degree of the edge of the wafer 110 is measured. The working chamber 10A has a first sensor 210 and a second sensor 212. The first sensor 210 is configured to measure a first height H1 of the wafer 110 at the first position, and the second sensor 212 is configured to measure a second height H2 of the wafer 110. In some embodiments, the first sensor 210 and the second sensor 212 may be contact sensors obtaining the height distribution of each portion by scanning height changes of the surface of the wafer 110.

In the present embodiment, the first height H1 is the average height on the wafer 110 at a first distance R1 from the center of the wafer 110, and the second height H2 is the average height on the wafer 110 at a second distance R2 from the center of the wafer 110. In particular, the first height H1 and the second height H2 are both the height from the contact surface of the wafer and the working chamber 10A to the surface at the opposite side of the wafer. In some embodiments, the range of the first distance R1 is 0.4 to 0.6 of a wafer radius R, and the range of the second distance R2 is 0.8 to 1.0 of the wafer radius R. That is, the first height H1 is the height of the middle portion of the wafer 110, and the second height H2 is the height of the edge portion of the wafer 110. In general, the central portion of the wafer, that is, warping does not occur to the wafer within 0.4 wafer radii from the center of the wafer 110, so only the heights of the central portion and the edge portion need to be measured.

When measuring the first height H1 and the second height H2, the wafer 110 is rotated along the center of the wafer, and the surface of the wafer 110 is scanned by the first sensor 210 and the second sensor 212, and the scanned height data is stored and transmitted to the magnetic levitation control system (not shown). In the magnetic levitation control system, the scanned height data is processed, for example, calculations such as correction and averaging are performed on the height data to obtain the first height H1 and the second height H2 of the wafer 110. The specific processing process is explained below.

According to the measurement result, if the first height H1 is equal to the second height H2, the wafer 110 is flat. If the first height H1 is less than the second height H2, the edge of the wafer 110 is tilted upward. If the first height H1 is greater than the second height H2, the edge of the wafer 110 is bent downward.

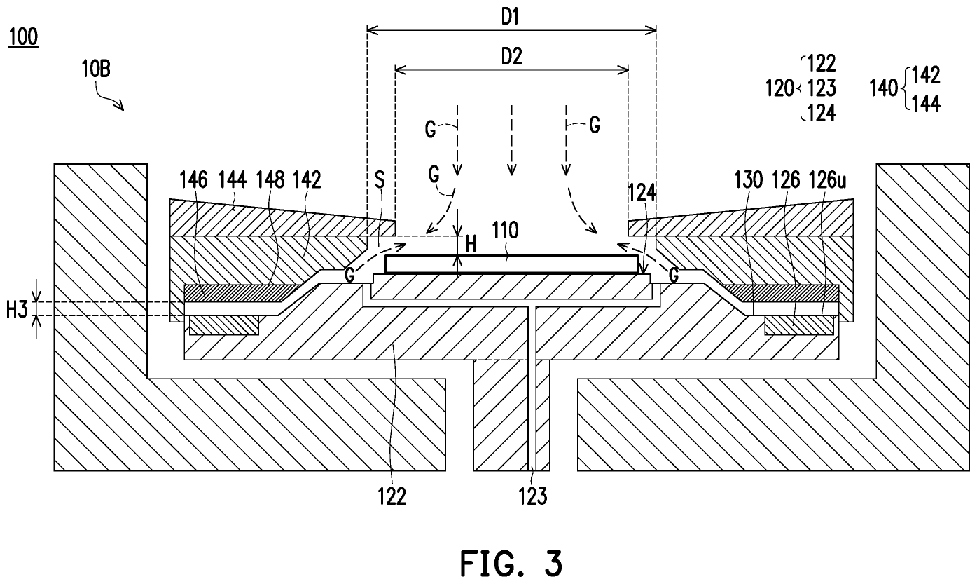

FIG. 3 is a schematic diagram of a wafer processing apparatus according to an embodiment of the invention. Please refer to FIG. 3.

The wafer processing apparatus 100 is located in the chamber 10B shown in FIG. 1. The wafer processing apparatus 100 is configured to interact with the wafer 110 using a reactive gas G. The wafer processing apparatus 100 includes a base 120, an air guide device 140, a first magnet 126, a second magnet 146, and a magnetic levitation control system 200.

The base 120 has a carrying plane 124, and the carrying plane 124 is configured to carry the wafer 110. The air guide device 140 is disposed circumferentially above the base 120. There is a space S between the base 120 and the air guide device 140, so that the reactive gas G flows in the space S.

As shown in FIG. 3, the first magnet 126 is disposed at a periphery of the base 120. The second magnet 146 is disposed at a periphery of the air guide device 140 and opposite to the first magnet 126.

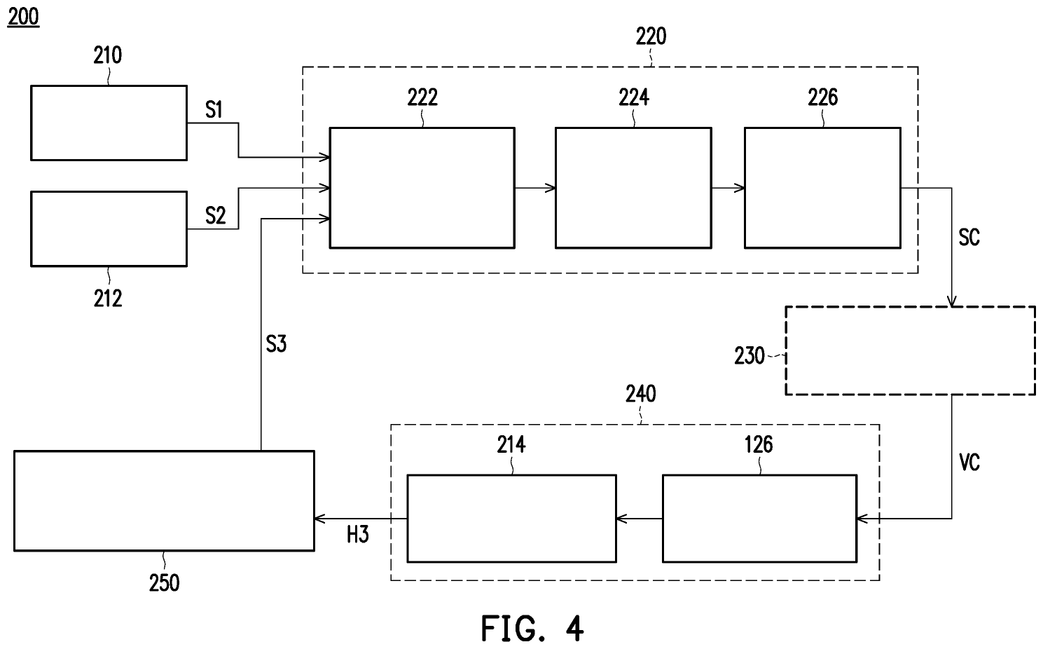

In addition, the wafer processing apparatus 100 further includes the magnetic levitation control system 200 (shown in FIG. 4 and described below). The magnetic levitation control system 200 is electrically connected to the first magnet 126, and according to the difference of the second height H2 and the first height H1 of the wafer 110, the magnetic force between the first magnet 126 and the second magnet 146 is controlled to change a distance H3 between the base 120 and the air guide device 140.

The base 120 is described below.

The base 120 includes a heater 122 and a carrying plane 124. As shown in FIG. 3, the carrying plane 124 is located on the heater 122. The carrying plane 124 is configured to carry the wafer 110.

The upper surface of the heater 122 is the carrying plane 124 configured to carry the wafer 110. The heater 122 may be configured to heat the wafer 110 to accelerate the reaction between the reactive gas G and the wafer 110.

The heater 122 further includes an air channel 123 connected to the outside and configured to introduce the reactive gas G from below the wafer 110. The air channel 123 is on the heater 122 and has a plurality of outlets on the upper surface outside the carrying plane 124 to accelerate the reaction between the reactive gas G and the wafer 110.

The periphery of the base 120 includes a second carrying plane 130. The second carrying plane 130 surrounds the periphery of the base 120. In some embodiments, the second carrying plane 130 may also be partially annular, but the disclosure is not limited thereto. As shown in FIG. 3, the second carrying plane 130 and the carrying plane 124 are located at different horizontal heights.

As shown in FIG. 3, the first magnet 126 is disposed at the second carrying plane 130, and the first magnet 126 is embedded in the heater 122. In some embodiments, an upper surface 126u of the first magnet 126 is at the same height as the second carrying plane 130.

The air guide device 140 is described below.

The air guide device 140 includes an air guide ring 142 and a non-contact ring 144. There is the space S between the air guide ring 142 and the wafer 110 so that the reactive gas G passes through and the reactive gas G may effectively be in contact with the surface of the wafer 110.

The non-contact ring 144 is disposed above the air guide ring 142. An inner diameter D2 of the non-contact ring 144 is less than an inner diameter D1 of the air guide ring 142 to accurately guide the reactive gas G into the space S between the base 120 and the air guide device 140.

Moreover, in some embodiments, the projection of the inner diameter D2 of the non-contact ring 144 along the normal direction of the carrying plane 124 is overlapped with the wafer 110, that is, the projection of the inner edge of the non-contact ring 144 on the wafer 110 is located within the wafer 110. Therefore, the portion of the non-contact ring 144 is coincided with the wafer 110 in the vertical direction.

As shown in FIG. 3, the distance of the upper surface of the wafer 110 and the bottom surface of the non-contact ring 144 is H. By controlling the distance H to be at an appropriate distance, the speed of the reactive gas G flowing into the space S may be effectively controlled, so that the film thickness of the reactive gas G deposited at the edge of the wafer 110 may be controlled to an appropriate thickness. When the distance H is too large, the flow rate of the reactive gas G into the space S is too large, causing the film thickness of the reactive gas G deposited at the edge of the wafer 110 to be too large. When the distance H is too small, the flow rate of the reactive gas G into the space S is too small, causing the film thickness of the reactive gas G deposited at the edge of the wafer 110 to be too small. In some embodiments, the distance H is approximately between 3 mm and 10 mm, but is not limited thereto and may have other values based on actual needs.

Please refer further to FIG. 3. The air guide ring 142 has a third carrying plane 148. The third carrying plane 148 surrounds the periphery of the air guide ring 142. In some embodiments, the third carrying plane 148 is annular, and may also be partially annular, but the disclosure is not limited thereto. The third carrying plane 148 is opposite to the second carrying plane 130 of the base 120. Moreover, the second magnet 146 is disposed on the third carrying plane 148.

As shown in FIG. 3, the first magnet 126 and the second magnet 146 are opposite to each other. There is the magnetic levitation distance H3 between the heater 122 and the air guide ring 142. In some embodiments, the first magnet 126 is an electromagnet that may generate a magnetic field by passing an electric current. The magnetic field direction of the first magnet 126 is a vertical direction and opposite to the magnetic field direction of the second magnet. In some embodiments, the second magnet 146 is a permanent magnet, and the magnetic field direction of the second magnet 146 is a vertical direction. Therefore, when current flows through the first magnet 126, a magnetic field opposite to the magnetic field direction of the second magnet 146 is generated. For example, when the magnetism of the second magnet 146 is such that the N pole faces upward and the S pole faces downward (or the S pole faces upward and the N pole faces downward), the magnetism of the first magnet 126 after being energized corresponds to the magnetism of the second magnet 146 such that the S pole faces upward and the N pole faces upward (or the N pole faces upward and the N pole faces downward). Therefore, by means of the same-pole repulsion between the first magnet 126 and the second magnet 146, mutual repulsive magnetic force may be generated between the base 120 and the air guide device 140. Thereby, the magnetic levitation distance H3 between the base 120 and the air guide device 140, that is, between the heater 122 and the air guide ring 142, is controlled. By adjusting the current flowing through the first magnet 126, the magnetic field intensity of the first magnet 126 may be changed, and the distance H between the non-contact ring 144 and the wafer 110 may be adjusted by mutual repulsion of the magnetic field with the second magnet 146.

In some embodiments, the number of the first magnet 126 is greater than one and the number of the second magnet 146 is greater than one. In some embodiments, the number of the first magnet 126 is equal to the number of the second magnet 146. In some embodiments, the first magnet 126 and the second magnet 146 are uniformly distributed along the periphery of the heater 122 and the periphery of the air guide ring 142 respectively, so that the magnetic force acting on the air guide device 140 between the first magnet 126 and the second magnet 146 is uniformly distributed.

The following is a detailed description of how the magnetic levitation control system 200 controls the magnetic force between the first magnet 126 and the second magnet 146 according to the difference between the second height H2 and the first height H1 of the wafer 110 to change the magnetic levitation distance H3 between the base 120 and the air guide device 140, that is, between the heater 122 and the air guide ring 142.

FIG. 4 is a schematic diagram of a magnetic levitation control system according to an embodiment of the invention. Please refer to FIG. 4. The magnetic levitation control system 200 includes: the first sensor 210 and the second sensor 212. The first sensor 210 is configured to measure the first height H1 of the wafer 110 at the first position, and the second sensor 212 is configured to measure the second height H2 of the wafer 110. As shown in FIG. 2, the first sensor 210 and the second sensor 212 are located in the chamber 10A.

The magnetic levitation control system 200 further includes a third sensor 214. The third sensor 214 is configured to measure the magnetic levitation distance H3 between the base 120 and the air guide device 140, that is, between the heater 122 and the air guide ring 142. In some embodiments, the third sensor 214 may be located on the heater 122 of the base 120 or on the air guide ring of the air guide device 140 and configured to measure the distance between the first magnet 126 on the base 120 and the second magnet 146 on the air guide device 140, and the disclosure is not limited thereto. In some embodiments, the third sensor may detect the distance between the first magnet 126 and the second magnet 146 using ultrasound, infrared, laser, or other methods, and the disclosure is not limited thereto.

As shown in FIG. 4, the magnetic levitation control system 200 further includes a controller 220, a magnetic levitation driver 230, a magnetic levitation system 240, and a signal conditioning box 250. As shown in FIG. 4, the controller 220, the magnetic levitation driver 230, the magnetic levitation system 240, and the signal conditioning box 250 are electrically connected to each other.

As shown in FIG. 4, the controller 220 is electrically connected to the first sensor 210, the second sensor 212, the signal conditioning box 250, and the magnetic levitation driver 230. The controller 220 receives the first signal S1 corresponding to the first height H1 from the first sensor 210, the second signal S2 corresponding to the second height H2 from the second sensor 212, the third signal S3 corresponding to the magnetic levitation distance H3 from the signal conditioning box 250, and generates a control signal SC according to the first signal S1, the second signal S2, and the third signal S3 and inputs the control signal to the magnetic levitation driver 230.

Specifically, the controller 220 includes a digital signal processor (DSP) 222 and programmable logic controllers (PLC) 224 and 226.

The first signal S1 corresponding to the first height H1 from the first sensor 210, the second signal S2 corresponding to the second height H2 from the second sensor 212, and the third signal S3 corresponding to the magnetic levitation distance H3 from the signal conditioning box 250 are input to the digital signal processor 222 of the controller 220 respectively. The digital signal processor 222 processes and analyzes the first signal S1 and the second signal S2 to obtain the first height H1 corresponding to the first signal S1 and the second height H2 corresponding to the second signal S2. Moreover, the digital signal processor 222 processes and analyzes the third signal S3 to obtain the magnetic levitation distance H3 corresponding to the third signal S3.

Next, the first height H1, the second height H2, and the magnetic levitation distance H3 are input to the programmable logic controller 224 to calculate the desired magnetic levitation height, so that the distance of the upper surface of the wafer 110 and the bottom surface of the non-contact ring 144 is an ideal distance H.

Specifically, the warpage degree of the edge of the wafer 110 may be known via the difference between the first height H1 and the second height H2. According to the warpage degree of the edge of the wafer 110, the desired magnetic levitation height between the base 120 and the air guide 140 may be calculated, so that the distance between the upper surface of the wafer 110 and the bottom surface of the non-contact ring 144 is H.

After the programmable logic controller 224 calculates the desired magnetic levitation height between the base 120 and the air guide device 140, the programmable logic controller 224 transmits the desired magnetic levitation height to the programmable logic controller 226, and the programmable logic controller 226 calculates the corresponding magnetic force intensity between the first magnet 126 and the second magnet 146 corresponding to the desired magnetic levitation height. In some embodiments, the desired magnetic force intensity is related to the number and the distribution of the first magnet 126 and the second magnet 146 and related to the weight of the device needing magnetic levitation, such as including the weight of, for example, the air guide device 140.

After the programmable logic controller 226 calculates the corresponding magnetic force intensity between the first magnet 126 and the second magnet 146 corresponding to the desired magnetic levitation height, the programmable logic controller 226 generates the control signal SC and inputs the control signal to the magnetic levitation driver 230.

In some embodiments, the programmable logic controller 224 and the programmable logic controller 226 may be combined into a single programmable logic controller.

In some embodiments, the controller 220 is a digital-to-analog converter converting the received digital signals: the first signal S1, the second signal S2, and the third signal S3 into an analog signal control signal SC.

In some embodiments, the controller 220 may include a calculator, a micro controller unit (MCU), a central processing unit (CPU), or other programmable controllers (microprocessors), digital signal processors (DSP), programmable controllers, application-specific integrated circuits (ASIC), programmable logic devices (PLD), or other similar devices. In some embodiments, the function of the controller 220 may be performed in software.

Please refer further to FIG. 4. The magnetic levitation driver 230 outputs a control voltage VC to the magnetic levitation system 240 according to the received control signal SC to drive the first magnet 126. According to some embodiments, the magnetic levitation driver may be a power supply or a device having a similar function, but the disclosure is not limited thereto.

Please refer further to FIG. 4. The magnetic levitation system 240 includes the first magnet 126 and the third sensor 214. The first magnet 126 of the magnetic levitation system 240 generates magnetic force according to the control voltage VC output by the magnetic levitation driver 230. The third sensor 214 measures the magnetic levitation distance H3 and transmits the magnetic levitation distance H3 to the signal conditioning box 250. As shown in FIG. 3, the magnetic levitation distance H3 is the distance between the first magnet 126 and the second magnet 146.

The signal conditioning box 250 is configured to generate the third signal S3 corresponding to the magnetic levitation distance H3 according to the magnetic levitation distance H3, and input the third signal S3 to the digital signal processor 222 of the controller 220. In some embodiments, the signal conditioning box 250 is an analog-to-digital converter converting the analog signal magnetic levitation distance H3 into the digital signal: the third signal S3.

Therefore, via the first detector 210 and the second detector 212, the first height H1 and the second height H2 of the wafer 110 may be measured to measure the warpage degree of the wafer 110. The magnetic levitation distance H3 between the heater 122 and the air guide ring 142 may be measured via the third sensor 214. These signals are input into the magnetic levitation control system 220 and may be configured to change the magnetic levitation distance H3 between the heater 122 and the air guide ring 142 so that the distance H between the non-contact ring 144 and the wafer 110 is constant.

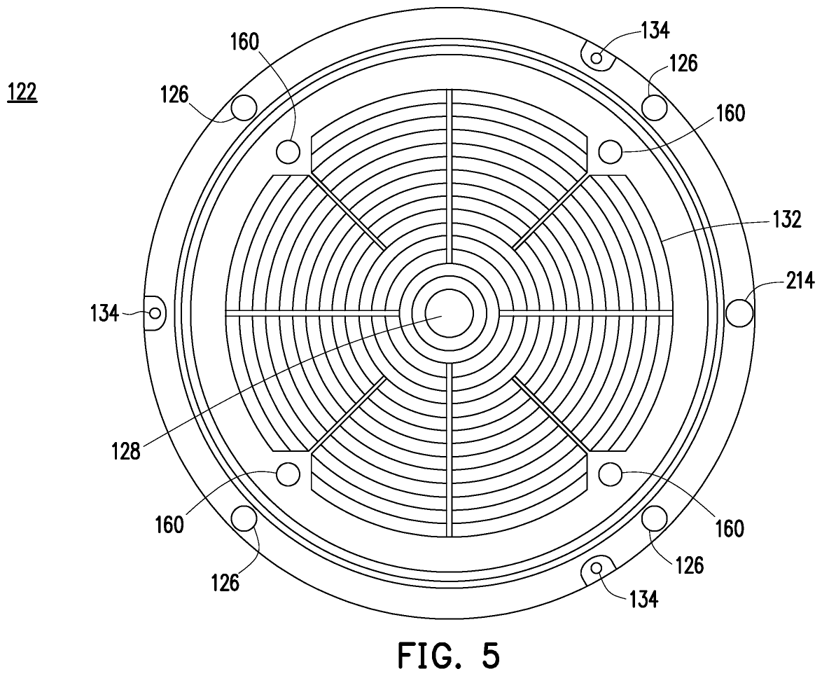

FIG. 5 is a top view of a base according to an embodiment of the invention.

Referring to FIG. 5, the upper surface of the heater 122, that is, the carrying plane 124, includes a plurality of heating rings 132. When the wafer 110 is placed on the carrying plane 124, the wafer 110 may be heated via the heating rings 132 to accelerate the reaction between the reactive gas G and the wafer 110. In some embodiments, the heating rings 132 are electric heaters, but the disclosure is not limited thereto.

As shown in FIG. 5, the base 120 further includes a vacuum port 128, and the vacuum port 128 is located at the carrying plane 124 and configured to generate a low-pressure area between the wafer 110 and the vacuum port 128. Specifically, the vacuum port 128 is connected to an external vacuum device. When the wafer 110 is placed at the carrying plane 124, a sealed space is formed between the wafer 110 and the vacuum portion. Therefore, when the vacuum device evacuates the sealed space, the pressure at the vacuum port 128 of the wafer 110 is less than the chamber pressure. Therefore, the wafer 110 may be tightly adsorbed on the carrying plane 124 to prevent the wafer 110 from moving randomly on the carrying plane 124.

As shown in FIG. 5, the heater 122 has a plurality of first magnets 126 uniformly distributed along the circumference of the heater 122. In the present embodiment, the number of the first magnets 126 is four, but the disclosure is not limited thereto. The number of the first magnets 126 may be two or more than two, and the number is determined according to actual needs. In other embodiments, the first magnets 126 may be distributed along a circle, and the distance between any two adjacent magnets may be different. Via the distribution of the first magnets 126, a uniform repulsive force may be generated on the air guide device 140, so that when the air guide device 140 is moved in the vertical direction, the horizontal plane may be kept stable.

As shown in FIG. 5, the heater 122 further includes the third sensor 214 configured to measure the distance H3 between the heater 122 and the air guide ring 142.

As shown in FIG. 5, the heater 122 further includes a plurality of wafer lifting pin channels 160 so that the wafer placed above the heater 122 may be moved via the plurality of wafer lifting pin channels 160. Specifically, by raising and lowering the wafer lifting pin channels 160, the wafer placed above the heater 122 may be raised and lowered accordingly. As shown in FIG. 5, the wafer lift pin channels 160 are uniformly distributed along the circumference of the heater 122. In the present embodiment, the number of the wafer lifting pin channels 160 is four, but the disclosure is not limited thereto. In some embodiments, the number of the wafer lift pin channels 160 is greater than or equal to three.

As shown in FIG. 5, the heater 122 further includes a plurality of through holes 134. The through holes 134 are configured to fix the air guide device 140 so that the air guide device may only move in the vertical direction. Therefore, when the first magnets 126 pass an electric current and generate repulsive magnetic force with the second magnet 146, the air guide device 140 may move in the vertical direction to avoid the horizontal plane of the air guide device 140 from tilting.

As shown in FIG. 5, the through holes 134 and the wafer lifting pin channels 160 are uniformly distributed along the circumference on the heater 122. In the present embodiment, the number of the through holes 134 is three, but the disclosure is not limited thereto. In the present embodiment, the number of the through holes 134 and the wafer lifting pin channels 160 may be three or more than three, and the number is determined according to actual needs.

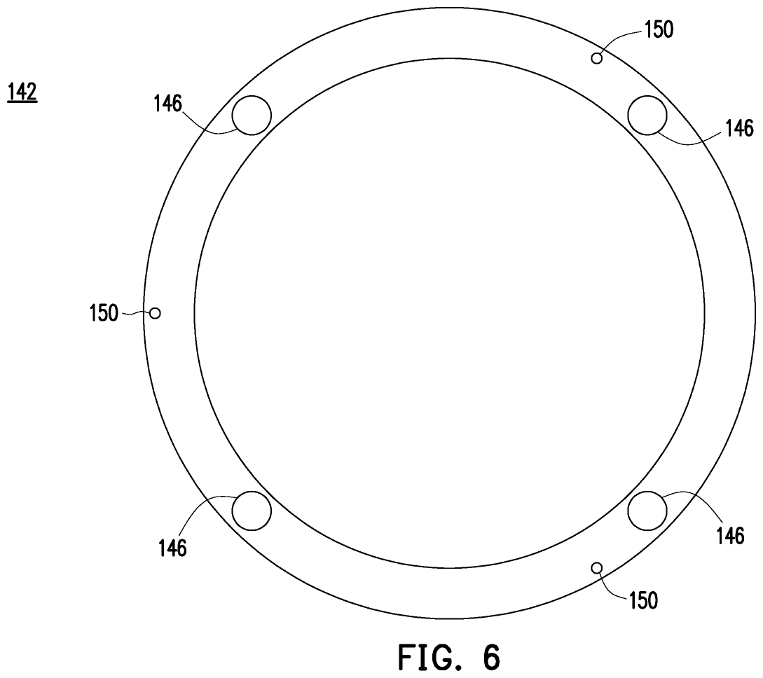

FIG. 6 is a top view of an air guide ring according to an embodiment of the invention.

Please refer to FIG. 6. As shown in FIG. 6, the air guide ring 142 is provided with a plurality of second magnets 146 uniformly distributed along the circumference of the air guide ring 142. The number and the position of the second magnets 146 correspond to the number and the position of the first magnets 126. In the present embodiment, the number of the second magnets 146 is four, but the disclosure is not limited thereto. The number of the second magnets 146 may be two or more than two, and the number is determined according to actual needs. In other embodiments, the second magnets 146 may be distributed along a circle, and the distance between any two adjacent magnets may be different.

As shown in FIG. 6, the air guide ring 142 further includes a plurality of through holes 150 fixed with the through holes 134 of the heater 122 shown in FIG. 5 to limit the movement direction of the air guide device 140 to the vertical direction, so that the air guide device 140 may move in the vertical direction along the wafer lifting pin channels 160 to prevent the horizontal plane of the air guide device 140 from tilting.

As shown in FIG. 6, the number and the position of the through holes 150 correspond to the through holes 134. In some embodiments, the through holes 150 are uniformly distributed along the circumference on the air guide ring 142. In the present embodiment, the number of the through holes 154 is three, but the disclosure is not limited thereto. In the present embodiment, the number of the through holes 150 may be three or more than three, and the number is determined according to actual needs.

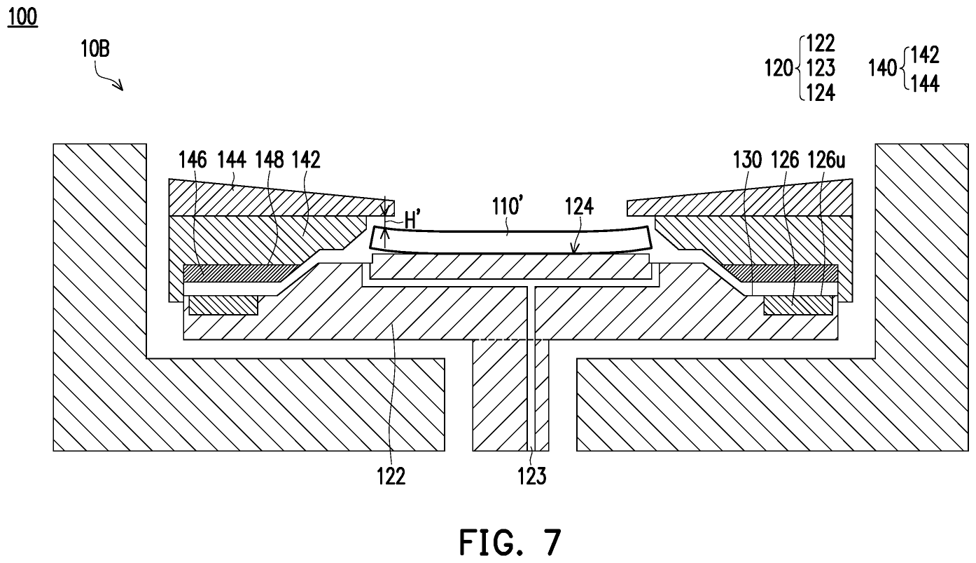

FIG. 7 is a schematic diagram of a wafer processing apparatus according to an embodiment of the invention. As shown in FIG. 7, in some embodiments, the edge of a wafer 110′ is tilted upward, thus causing a distance H′ of the upper surface of the wafer 110′ and the bottom surface of the non-contact ring 144 to be less than the distance H shown in FIG. 3. Therefore, the flow rate of the reactive gas G into the space S is too small, causing the film thickness of the reactive gas G deposited at the edge of the wafer 110 to be too small. Via the magnetic levitation control system 200, the magnetic force between the first magnets 126 and the second magnets 146 may be controlled, so that the distance H′ is increased to H to control the speed of the reactive gas G flowing into the space S, and thereby control the film thickness of the reactive gas G deposited at the edge of the wafer 110′ to an appropriate thickness.

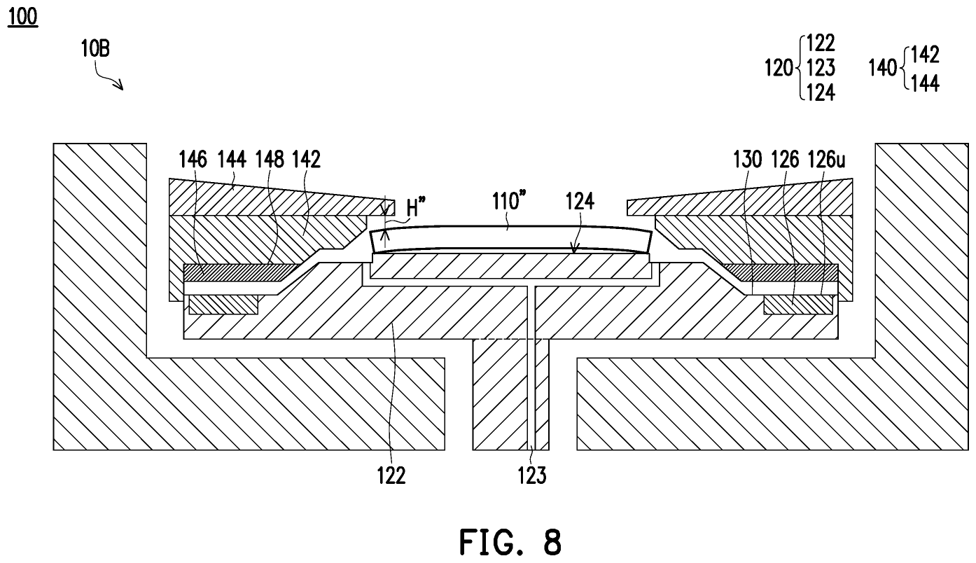

FIG. 8 is a schematic diagram of a wafer processing apparatus according to an embodiment of the invention. As shown in FIG. 8, in some embodiments, the edge of a wafer 110″ is bent downward, thus causing a distance H″ of the upper surface of the wafer 110″ and the bottom surface of the non-contact ring 144 to be greater than the distance H shown in FIG. 3. Therefore, the flow rate of the reactive gas G into the space S is too large, causing the film thickness of the reactive gas G deposited at the edge of the wafer 110 to be too large. Via the magnetic levitation control system 200, the magnetic force between the first magnets 126 and the second magnets 146 may be controlled, so that the distance H″ is decreased to H to control the speed of the reactive gas G flowing into the space S, and thereby control the film thickness of the reactive gas G deposited at the edge of the wafer 110″ to an appropriate thickness.

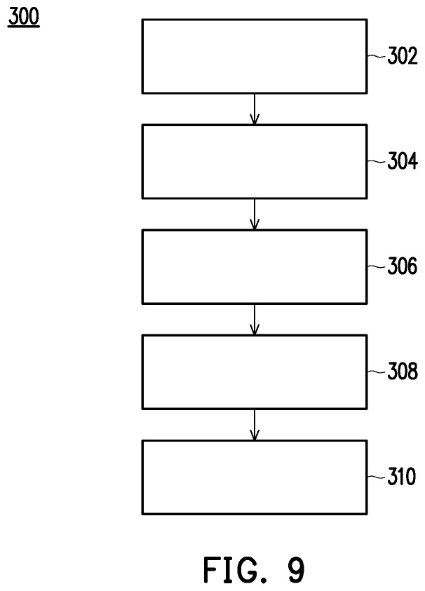

FIG. 9 is a flowchart of a coating method according to an embodiment of the invention. Via a flowchart 300, the distance between the wafer and the air guide device may be adjusted according to warpage degree of the wafer to generate a thin film with uniform thickness.

Please refer to FIG. 1 to FIG. 6 and FIG. 9 at the same time.

In step 302, the first sensor 210 is configured to measure the first height H1 of the wafer 110 at the first position, and the second sensor 212 is configured to measure the second height H2 of the wafer 110 to obtain the height difference between the edge and the central portion of the wafer 110.

In step 304, the wafer 110 is placed on the carrying plane 124.

In step 306, the magnetic levitation control system 200 is used to control the height of the air guide device 140 so that the distance between the wafer 110 and the non-contact ring of the air guide device 140 is H.

In step 308, vacuum is generated at the vacuum port 128 to fix the wafer 110, and the pressure between the wafer 110 and the carrying plane 124 is detected to confirm whether the wafer 110 is fixed on the carrying plane 124.

In step 310, the reactive gas G is introduced so that the reactive gas G may flow into the space S and react with the surface of the wafer 110 to form the desired thin film.

Based on the above, in the invention, according to the height difference of the central portion and the edge of the wafer, the distance between the base and the air guide device may be controlled via the magnetic levitation control system of the wafer processing apparatus to ensure that the gap of the air guide device and the wafer is a fixed value, so that the reactive gas in the chemical vapor deposition process may uniformly surround the wafer surface, so that the thickness of the thin film formed on the wafer surface is uniform.

What is claimed is:

1. A wafer processing apparatus, configured to interact with a wafer using a reactive gas, comprising:
a base having a carrying plane, the carrying plane is configured to carry the wafer, and the wafer has a first height and a second height;
an air guide device disposed circumferentially above the base, and there is a space between the base and the air guide device so that the reactive gas flows in the space;
a first magnet disposed at a periphery of the base;
a second magnet disposed at a periphery of the air guide device and opposite to the first magnet; and
a magnetic levitation control system electrically connected to the first magnet and controlling a magnetic force between the first magnet and the second magnet according to a difference of the second height and the first height to change a distance between the base and the air guide device.

2. The wafer processing apparatus of claim 1, wherein the base comprises a heater configured to heat the wafer, and the carrying plane is located on the heater.

3. The wafer processing apparatus of claim 2, wherein the base further comprises a vacuum port, and the vacuum port is located on the carrying plane and configured to generate a low-pressure area between the wafer and the vacuum port.

4. The wafer processing apparatus of claim 1, wherein the first height is an average height on the wafer at a first distance from a center of the wafer, and the second height is an average height on the wafer at a second distance from the center of the wafer, wherein a range of the first distance is 0.4 to 0.6 of a wafer radius, and a range of the second distance is 0.8 to 1.0 of the wafer radius.

5. The wafer processing apparatus of claim 1, wherein the periphery of the base comprises a second carrying plane, the first magnet is disposed at the second carrying plane, and an upper surface of the first magnet is at a same height as the second carrying plane.

6. The wafer processing apparatus of claim 1, wherein the air guide device comprises an air guide ring, the air guide ring has a third carrying plane, the third carrying plane is opposite to the base, and the second magnet is disposed on the third carrying plane.

7. The wafer processing apparatus of claim 6, wherein the air guide device further comprises a non-contact ring, the non-contact ring is disposed above the air guide ring, and an inner diameter of the non-contact ring is less than an inner diameter of the air guide ring.

8. The wafer processing apparatus of claim 7, wherein the air guide device further comprises a projection of the inner diameter of the non-contact ring along a normal direction of the carrying plane overlapping the wafer.

9. The wafer processing apparatus of claim 1, wherein the first magnet is an electromagnet and the second magnet is a permanent magnet.

10. The wafer processing apparatus of claim 1, wherein a number of the first magnet is greater than one, and a number of the second magnet is greater than one.

11. The wafer processing apparatus of claim 1, wherein a number of the first magnet is equal to a number of the second magnet.

12. The wafer processing apparatus of claim 1, wherein the magnetic levitation control system comprises: a first sensor and a second sensor, wherein the first sensor is configured to measure the first height of the wafer, and the second sensor is configured to measure the second height of the wafer.

13. The wafer processing apparatus of claim 12, wherein the magnetic levitation control system further comprises: a third sensor, wherein the third sensor is configured to measure a magnetic levitation distance between the base and the air guide device.

14. The wafer processing apparatus of claim 13, wherein the magnetic levitation control system further comprises: a controller, a magnetic levitation driver, a magnetic levitation system, and a signal conditioning box, wherein
the controller is electrically connected to the first sensor, the second sensor, the signal conditioning box, and the magnetic levitation driver, the controller receives a first signal corresponding to the first height from the first sensor, a second signal corresponding to the second height from the second sensor, a third signal corresponding to the magnetic levitation distance from the signal conditioning box, and generates a control signal according to the first signal, the second signal, and the third signal and inputs the control signal to the magnetic levitation driver,
the magnetic levitation driver is electrically connected to the magnetic levitation system, and the magnetic levitation driver outputs a control voltage to the magnetic levitation system according to the received control signal,
the magnetic levitation system comprises the first magnet and the third sensor, the magnetic levitation system is electrically connected to the signal conditioning box, the first magnet generates a magnetic force according to the control voltage, and the third sensor measures the magnetic levitation distance and transmits the magnetic levitation distance to the signal conditioning box,
the signal conditioning box generates the third signal corresponding to the magnetic levitation distance according to the magnetic levitation distance.

15. The wafer processing apparatus of claim 14, wherein the controller is a digital-to-analog converter.

16. The wafer processing apparatus of claim 14, wherein the signal conditioning box is an analog-to-digital converter.

17. The wafer processing apparatus of claim 1, wherein the wafer processing apparatus further comprises a plurality of wafer lifting pin channels, so that the wafer is moved via the plurality of wafer lifting pin channels.
